(19) United States
(12) Patent Application Publication
(10) Pub. No.: US 2025/0247063 A1
(43) Pub. Date: Jul. 31, 2025

(54) INPUT STAGE FOR A SIGNAL PROCESSING CIRCUIT

(71) Applicant: Renesas Design (UK) Limited, Bourne End (GB)

(72) Inventor: Jindrich Švorc, Prague (CZ)

(73) Assignee: Renesas Design (UK) Limited, Bourne End (GB)

(21) Appl. No.: 18/426,791

(22) Filed: Jan. 30, 2024

(51) Int. Cl. H03F 3/45

(52) U.S. Cl. CPC H03F 3/45775; H03F 3/45183; H03F 3/45273; H03F 2200/261

(57) ABSTRACT

An input stage for a signal processing circuit, the input comprising: a first differential pair; and a second differential pair; wherein the first differential pair and the second differential pairs have opposing skews which controls a voltage offset of the input stage.

### TECHNICAL FIELD

The present disclosure relates to an input stage for a signal processing circuit, the input stage comprising a first and a second differential pair.

### BACKGROUND

A differential pair is a configuration of two interconnected transistors to amplify an input signal. They are commonly used as an input stage of many amplifiers and comparators. However, a differential pair suffers a voltage offset as the two transistors are not completely identical due to the manufacturing process.

There are number of ways known in the prior art to trim the voltage offset of the differential pair, however these solutions all require the addition of components to the amplifier or comparator which leads to other problems such as the presence of parasitic capacitance or a change to the gain of the circuit.

It is an object of the disclosure to address one or more of the above mentioned limitations.

### SUMMARY

According to a first aspect of the disclosure there is provided an input stage for a signal processing circuit, the input comprising: a first differential pair; and a second differential pair; wherein the first differential pair and the second differential pairs have opposing skews which controls a voltage offset of the input stage.

Optionally, the signal processing circuit is one of an amplifier or a comparator.

Optionally, the amplifier is an operational transconductance amplifier.

Optionally, the first differential pair comprises a first transistor and a second transistor such that the first transistor and second transistor have a skew in a first direction. For instance, the first transistor could output a larger current than the second transistor for a skew in the direction of the first transistor.

Optionally, the second differential pair comprises a third transistor and a fourth transistor such that the third transistor and fourth transistor have a skew in a second direction, where the second direction is opposite to the first direction. For instance, the fourth transistor could output a larger current than the third transistor for a skew in the direction of the fourth transistor.

Optionally, the first transistor, second transistor, third transistor and fourth transistor are one of a metal oxide semiconductor or a bipolar transistor.

Optionally, the first transistor, second transistor, third transistor and fourth transistor each comprise an output terminal such that the output terminal of the first transistor and the third transistor are coupled together to form a positive node and the output terminal of the second transistor and the fourth transistor are coupled together to form a negative node.

For instance, the first transistor could be a metal oxide semiconductor and the output terminal could be a drain terminal.

For instance, the second transistor could be a metal oxide semiconductor and the output terminal could be a drain terminal.

For instance, the third transistor could be a metal oxide semiconductor and the output terminal could be a drain terminal.

For instance, the fourth transistor could be a metal oxide semiconductor and the output terminal could be a drain terminal.

Optionally, the positive node is configured to carry a first current and the negative node is configured to carry a second current.

Optionally, the first transistor and the third transistor each comprise a control terminal, the control terminals being configured to receive a positive input, such that the positive inputs of the control terminals of the first and second positive transistors are coupled together.

For instance, the first transistor could be a metal oxide semiconductor and the control terminal could be a gate terminal.

For instance, the third transistor could be a metal oxide semiconductor and the control terminal could be a gate terminal.

Optionally, the second transistor and the fourth transistor each comprise a control terminal, the control terminals being configured to receive a negative input, such that the negative inputs of the control terminals of the first and second negative transistors are coupled together.

For instance, the second transistor could be a metal oxide semiconductor and the control terminal could be a gate terminal.

For instance, the fourth transistor could be a metal oxide semiconductor and the control terminal could be a gate terminal.

Optionally, the first transistor, second transistor, third transistor and fourth transistor each further comprise an input terminal such that the input terminals of the first transistor and the second transistor are together coupled to form a first tail node and the input terminals of the third transistor and the fourth transistor are coupled together to form a second tail node.

For instance, the first transistor could be a metal oxide semiconductor and the input terminal could be a source terminal.

For instance, the second transistor could be a metal oxide semiconductor and the input terminal could be a source terminal.

For instance, the third transistor could be a metal oxide semiconductor and the input terminal could be a source terminal.

For instance, the fourth transistor could be a metal oxide semiconductor and the input terminal could be source terminal.

Optionally, the first tail node and the second tail node are configured to receive a bias current.

Optionally, the first bias current and the second bias current are equal and the bias currents are not adjusted.

Optionally, the first bias current and the second bias current are not equal and either: the bias current at the first tail node is adjusted; or the bias current at the second tail node is adjusted; or the bias current at the first differential pair and the second tail node are adjusted.

Optionally, the first current and the second current are equal after the bias current is adjusted.

Optionally, the bias current is adjusted by a trimming current.

Optionally, when the bias current is adjusted by the trimming current, the voltage offset is controlled such that the voltage offset of the input stage is minimised.

Optionally, when the bias current is adjusted by the trimming current, the voltage offset is controlled such that the voltage offset of the input stage is set to a pre-determined value.

Optionally, either: the trimming current is added to or taken away from the bias current at the first tail node; or the trimming current is added to or taken away from the bias current at the second tail node; or the trimming current is added to the bias current at the first tail node and the trimming current is taken away from the bias current at the second tail node; or the trimming current is taken away from the bias current at the first tail node and the trimming current is added to the bias current at the second tail node.

Optionally, the trimming current has an absolute value dependent on the skew of the first differential pair, the skew of the second differential pair and the voltage offset of the input stage.

According to a second aspect of the disclosure there is provided an apparatus comprising: a signal processing circuit, an input stage for the signal processing circuit, the input stage comprising a first differential pair and a second differential pair wherein the first differential pair and the second differential pair have opposing skews which minimise a voltage offset of the input stage.

It will be appreciated that the apparatus of the second aspect may include features as set out in relation to the first aspect and can incorporate other features as described herein.

According to a third aspect of the disclosure there is provided a method for minimizing a voltage offset of an input stage for a signal processing circuit, the method comprising: providing the input stage with a first differential pair and a second differential pair, wherein the first differential pair and the second differential pair have opposing skews.

Optionally, the first differential pair and the second differential pair are configured to receive a bias current; and the bias current of either the first differential pair, or the second differential pair, or both the first and the second differential pair is adjusted by a trimming current such that the voltage offset of the input stage is minimised.

It will be appreciated that the method of the third aspect may include using and/or providing features as set out in the first aspect and/or second aspect, and can incorporate other features as described herein.

### DESCRIPTION OF THE DRAWINGS

The disclosure is described in further detail below by way of example and with reference to the accompanying drawings, in which:

FIG. 1 is an example of an amplifier showing known solutions to trimming the voltage offset of a differential pair from the prior art;

FIG. 2 is an embodiment of an input stage for a signal processing circuit of the present disclosure;

FIG. 3A is another embodiment of an input stage for a signal processing circuit of the present disclosure;

FIG. 3B is a third embodiment of the input stage for a signal processing circuit of the present disclosure;

FIG. 4 is an example of a comparator comprising the input stage of FIG. 3A; and

FIG. 5 is an example of an amplifier comprising the input stage of FIG. 3B.

### DESCRIPTION

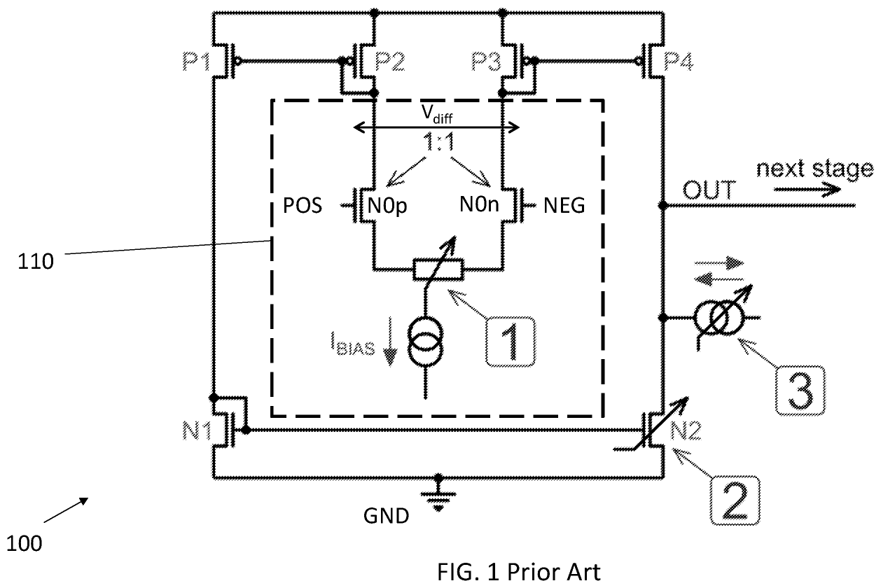

FIG. 1 is an example of an amplifier 100 showing a number of known solutions for trimming the voltage offset of a differential pair from the prior art. Each solution is labelled from 1 to 3 and each one would be implemented separately in a given amplifier 100 but have been shown in a single figure for conciseness. The amplifier 100 shown is an example of an operational transconductance amplifier (OTA). The OTA 100 has an input stage 110 comprising a single differential pair with two transistors N0p and N0n. Each transistor comprises a control terminal. The control terminal of one transistor (N0p) is configured to receive a positive input POS and has an operating voltage Vₚₒₛ. The control terminal of the other transistor (N0n) is configured to receive a negative input NEG with an operating voltage V_{neg}. Both N0p and N0n receive a bias current I_{BIAS} which is applied at their tail terminals in order to ensure that both transistors act within their active region. Operation in this region allows for N0p and N0n to amplify the voltage difference V_{diff} between Vₚₒₛ and V_{neg}, where V_{diff}=Vₚₒₛ-V_{neg}. The input stage 110 shown in FIG. 1 can also equally be applied to any other type of amplifier or a comparator.

After the input stage 110, the OTA is formed of a current mirror comprising transistors P1, P2, P3, P4, N1 and N2. The current mirrors take the amplified V_{diff} from the differential input pair and replicates the output current to pass onto the next stage. This next stage represents any circuit that an amplifier or OTA can be part of. The components N0p, Non, P1, P2, P3, P4, N1 and N2 all form part of the signal path for the OTA 100 as they are used to transmit the signal to the next stage of the circuit.

Ideally, the two transistors N0p and N0n are of the same size, in other words they have a 1:1 ratio. Therefore, in ideal operation if Vₚₒₛ=V_{neg} then the OTA 100 would be balanced and there would be no current present at OUT. However, POS and NEG are not identical due to a mismatch in tolerance during manufacturing of the transistors. This results in an inbuilt voltage offset into the OTA focussed at the input stage 110. There are a number of known ways in the prior art to account for this voltage offset. A selection are shown in FIG. 1 and are labelled 1 to 3, this is not an exhaustive list. Each of these techniques would be applied separately to the OTA 100 but have been shown in a single figure for conciseness. These techniques can be applied to the OTA 100 shown or to any other type of amplifier or comparator.

Technique 1 involves adding a digitally controlled resistor or trimmer into the sources of the input differential pair in order to digitally trim and change the current in either the positive branch or the negative branch such that the current mirror is balanced. However, this technique increases the complexity of the design of the OTA 100 and results in a decreased gain of the input stage 110 and can potentially degrade power supply rejection ratio by coupling noise into this sensitive nets. Technique 2 involves trimming of the voltage offset occurs in the current mirror by adding a bank of variable switches to form a digitally controlled current mirror. However, this increases the complexity of the design of the OTA 100 and also increases the parasitic capacitance which has a negative impact on the overall speed of the OTA. In technique 3, the trimming occurs before the OUT stage by either adding or removing a trimmed current value. However, this technique adds parasitic capacitance to the high impedance node, increases the complexity of design of OTA 100 and also slows the response of the OTA 100.

There are other techniques, however all the techniques shown in FIG. 1 and the others known in the art involve adding devices into the signal path which results in a change of the gain or add a parasitic capacitance to the circuit.

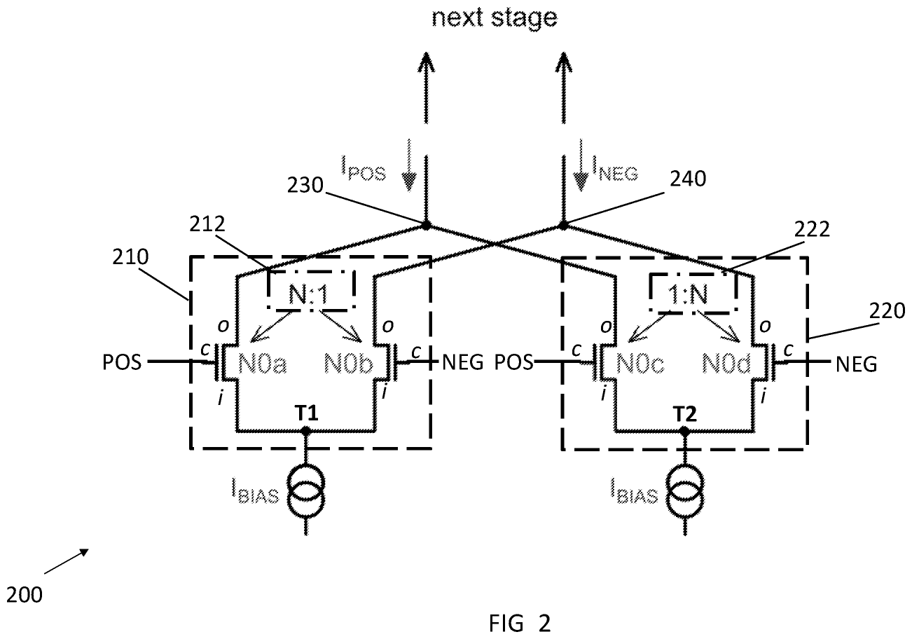

FIG. 2 is an embodiment of an input stage 200 of the present disclosure for a signal processing circuit in accordance with a first embodiment of the present disclosure. The signal processing circuit could be, for example, an amplifier, an OTA or a comparator. The input stage 200 comprises a first differential pair 210 and a second differential pair 220. The first differential pair 210 and the second differential pair 220 have opposing skews to control the voltage offset of the input stage. The meaning of opposing skews is discussed in more detail below.

The first differential pair 210 comprises a first transistor N0a and a second transistor N0b. The transistors N0a and N0b have a skew 212 in a first direction N:1. The second differential pair 220 comprises a third transistor N0c and a fourth transistor N0d. The transistors N0c and N0d have a skew 222 in a second direction 1:N. The skew 222 of the second differential pair 220 is in an opposite direction to the skew 212 of the first differential pair 210. The first and second skews each have a skewing factor N. The skewing factor N is set by designer with respect to the maximum possible mismatch of the input pair within some margin. It indicates the strength of one transistor in the differential pair relative to the other. For example, for the first differential pair 210, the skew is in the direction of N0a. This means that the first transistor N0a is stronger, and hence, produces a larger output current than the second transistor N0b. For the second differential pair 210, the skew is in the direction of N0d, such that the fourth transistor N0d produces a larger output than the third transistor N0c. Both N0a and N0d have the same skewing factor, therefore the skew of the first differential pair 210 and the second differential pair 220 is equal and opposite. The transistors N0a, N0b, N0c and N0d can be, for example, a metal oxide semiconductor or a bipolar transistor. Each of the first N0a, second N0b, third N0c and fourth N0d transistors comprise an output terminal o. The output terminal o of the first transistor N0a and the third transistor N0c are coupled together to form a positive node 230 which is configured to carry a first current I_{POS}. The output terminal o of the second transistor N0b and the fourth transistor N0d are coupled together to form a negative node 240 which is configured to carry a second current I_{NEG}. The first current I_{POS} and the second current I_{NEG} then passed onto the next stage. The next stage refers to the signal processing circuit that the input stage 200 is part of. This could be, for example, an amplifier or a comparator.

The first transistor N0a and the third transistor N0c each comprise a control terminal c. The control terminals c are configured to receive a positive input POS. The positive inputs POS for the control terminals c of the first and third transistors N0a and N0c are coupled together. The second transistor N0b and the fourth transistor N0d each comprise a control terminal c. The control terminals c are configured to receive a negative input NEG. The negative inputs NEG for the control terminals c of the second and fourth transistors N0b and N0d are coupled together.

Each of the first N0a, second N0b, third N0c and fourth N0d transistors further comprise an input terminal i. The input terminal i of the first transistor N0a and the second transistor N0b are connected together to form a first tail node T1. The input terminal i of the third transistor N0c and the fourth transistor N0d are connected together to form a second tail node T2. Both the first tail node T1 and the second tail node T2 are configured to receive a bias current I_{BIAS}.

The first, second, third and fourth transistors N0a, N0b, N0c and N0d could be, for example, a metal oxide semiconductors. For example, therefore, the control terminal c could be a gate terminal, the input terminal i could be a source terminal and the output terminal o could be a drain terminal.

In the embodiment of FIG. 2, the first differential pair 210 has an intended inbuilt skew 212 in one direction and the second differential pair 220 has the same skew in the other direction 222. Both differential pairs are supplied with bias current I_{BIAS}. The first current I_{POS} and the second current I_{NEG} are equal for this two-differential input stage 200 combination because the skewing N of the first differential pair 210 compensates for the skewing N of the second differential pair 220. Therefore, as the first current I_{POS} is equal to the second current I_{NEG} and the voltage offset is accounted for without affecting the signal path. The signal processing circuit comprising an input stage 200 will not have an affected gain or an additional parasitic capacitance and hence will not be slowed down.

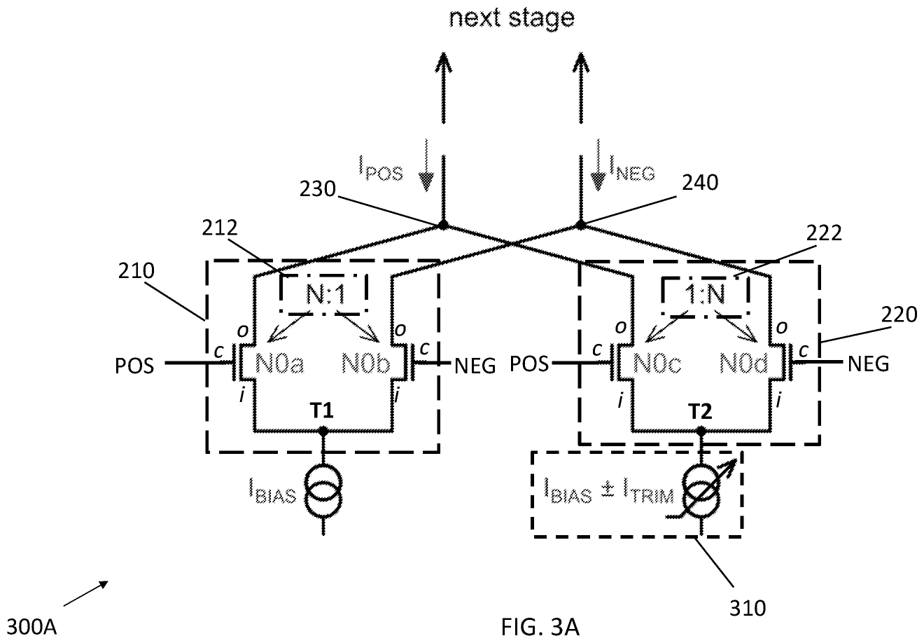

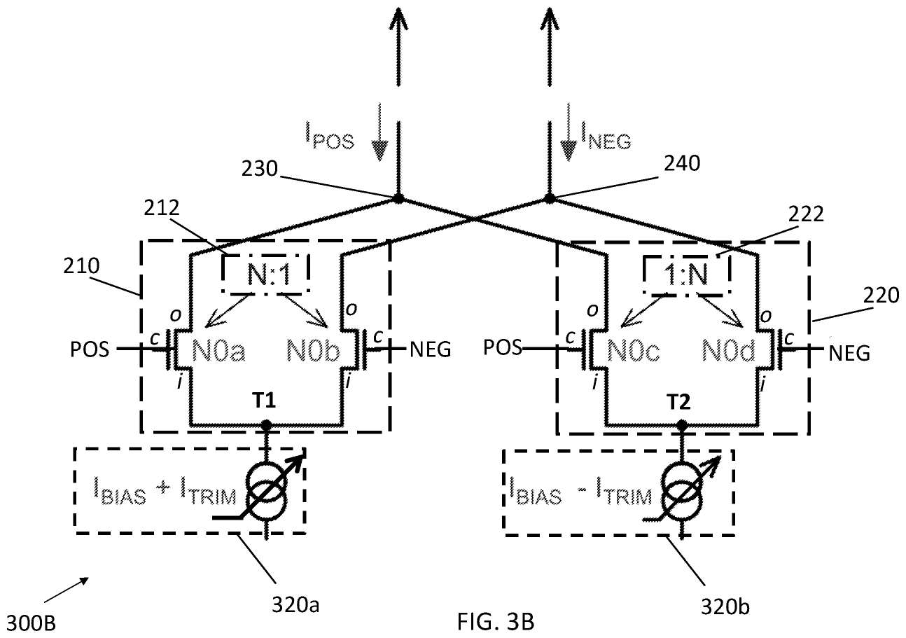

FIG. 3A shows an alternative embodiment of an input stage 300A of the present disclosure for a signal processing circuit in accordance with a second embodiment of the present disclosure. The signal processing circuit could be, for example, an amplifier, an OTA or a comparator. The input stage 300A is the same as input stage 200 with the addition of feature 310. Therefore, the same labelling has been kept for input stage 300A and the components are taken to have the same functionality and meaning as for input stage 200.

The input stage 200 is the theoretical ideal embodiment of the present disclosure, however, either the first differential pair 210 or the second differential pair 220 will be produce a larger current than the other due to manufacturing tolerances or other unpredictable random process variations. This mismatch exists as the manufacturing process is unable to create two completely identical transistors. Whilst they can be manufactured to be similar, they will never be exactly the same. The skewing N of the first differential pair and the second differential pair is chosen to be at least equal to or greater than the maximum expected manufacturing mismatch. However, as the mismatch can be greater than expected the skewing N cannot compensate for it alone in all cases. Therefore, the first current I_{POS} is not equal to I_{NEG} which is undesirable. Therefore, the bias current I_{BIAS} is adjusted by a trimming current I_{TRIM}. The trimming current I_{TRIM} is pre-set adjustment before implementing the input stage 300A in an amplifier or a comparator. The trimming current I_{TRIM} is set by shorting the positive input POS and the negative input NEG and changing the value of I_{TRIM} until the signal processing circuit trips (in the case of a comparator) or the output of the signal processing circuit goes from one rail to the other (in the case of the amplifier). The bias current can be adjusted at the second tail node T2 as shown in the input stage 300A by feature 310. The bias current I_{BIAS} is adjusted by either adding or removing a trimming current I_{TRIM}. The value of the trimming current I_{TRIM} could be either positive or negative. The adjustment to the bias current I_{BIAS} does not need to occur at the second tail node T2 but could happen instead at the first tail node T1.

In the embodiment of FIG. 3A, the bias current I_{BIAS} of the second differential pair 220 differs from the bias current of the first differential pair 210 by a trimming current I_{TRIM}. In this way, the voltage offset in the whole structure can be adjusted and compensated at the input stage. In other words, a change in I_{TRIM} can compensate for the unwanted voltage offset due to the fabrication process of the transistors N0a, N0b, N0c and N0d. Also changing the value of the trimming current I_{TRIM} can intentionally create a specific voltage offset if needed. This intentionally set voltage offset will be set with good accuracy and not with a random offset which can be needed in some cases. For example, a comparator with an accurate offset can partially compensate for a delay within the comparator, if the slope of the signal of the comparator is known. For the input stage 300A, the adjustment to the bias current I_{BIAS} could also be for the first differential pair 210 rather than the second differential pair 220. The signal processing circuit comprising an input stage 300A will not have an affected gain or an additional parasitic capacitance and hence will not be slowed down. The example embodiment input stage 300A can control the voltage offset without affecting the signal path.

FIG. 3B shows another alternative embodiment for an input stage 300B of the present disclosure for a signal processing circuit in accordance with a third embodiment of the present disclosure. The signal processing circuit could be, for example, an amplifier, an OTA or a comparator. The input stage 300B is the same as input stage 200 with the addition of features 320a and 320b. Therefore the same labelling has been kept for input stage 300B and the components are taken to have the same functionality and meaning as for input stage 200.

The input stage 300A applies one-sided trimming. Applying an adjustment to the bias current I_{BIAS} at only either the first tail node T1 or the second tail node T2 can change the DC operation point in the output of the signal processing circuit. For example, in an ideal circuit the expectation is that I_{POS}=I_{NEG}=I_{BIAS} when the input differential voltage is zero. However, for the embodiment 300A this is not true as the one-sided trimming changes the tail current such that I_{POS}=I_{NEG} but these currents are not equal to I_{BIAS}. This is due to the addition or subtraction of I_{TRIM} to one side only. Therefore, the steady-state biasing of the circuit (DC) is not kept the same and has been changed. To overcome this, the embodiment shown in FIG. 3B can also be used. The input stage 300B applies an adjustment 320a and 320b to the bias current I_{BIAS} at both the first tail node T1 for the first differential pair 210 and the second tail node T2 for the second differential pair 220. The adjustment is also in the form of a trimming current I_{TRIM} which can take either a positive or a negative value. The adjustment at the first tail node T1 is in an equal and opposite direction to the adjustment at the second tail node T2. For example, if the bias current I_{BIAS} at the first tail node T1 is adjusted as follows I_{BIAS}+I_{TRIM} then the bias current at the second tail node T2 will be adjusted as I_{BIAS}−I_{TRIM}. In another example, the bias current at T1 can be adjusted as I_{BIAS}−I_{TRIM} and the bias current at T2 can be adjusted as I_{BIAS}+I_{TRIM}. After the adjustment to the bias current, the first current I_{POS} is equal to the second current I_{NEG} and both the first and second currents are equal to the bias current I_{BIAS}. Hence, the voltage offset is accounted for without affecting the signal path. The signal processing circuit comprising an input stage 300B will not have an affected gain or an additional parasitic capacitance and hence will not be slowed down.

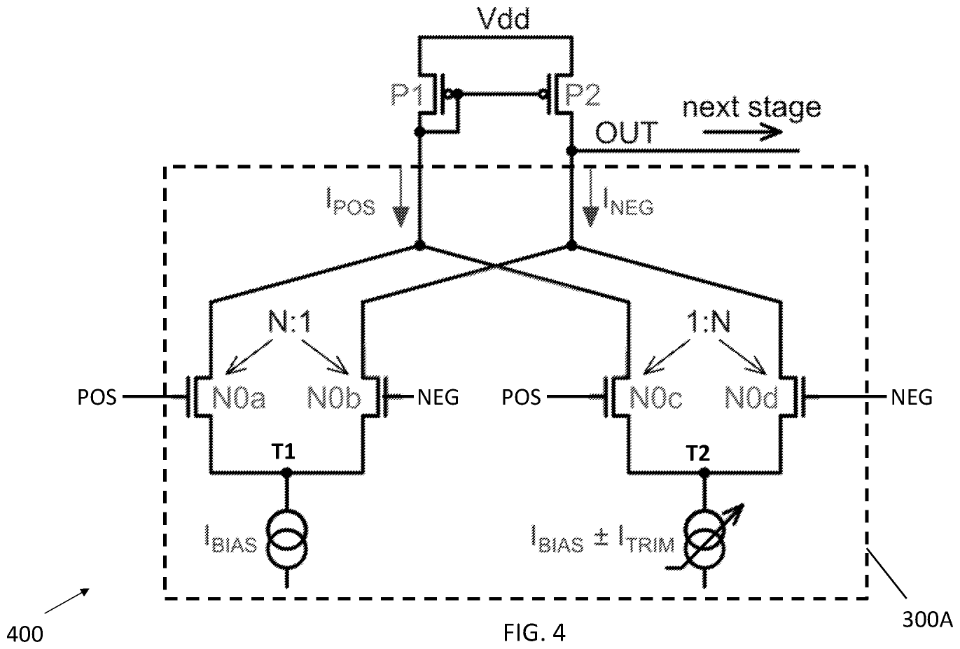

FIG. 4 is a diagram of an apparatus comprising a signal processing circuit 400 and an input stage 300A for a signal processing circuit 400, in accordance with a fourth embodiment of the present disclosure. The signal processing circuit 400 in this example embodiment is a comparator 400 which uses the example embodiment of the input stage 300A shown in FIG. 3A. The input stage 300A of FIG. 4 is taken to have the same functionality and meaning as the input stage 300A of f FIG. 3A. This embodiment of the input stage can also be used in other types of comparator circuits as well as different types of amplifier circuits. The alternative embodiment of the input stage of the present disclosure shown in FIG. 3B can also be used in the comparator 400.

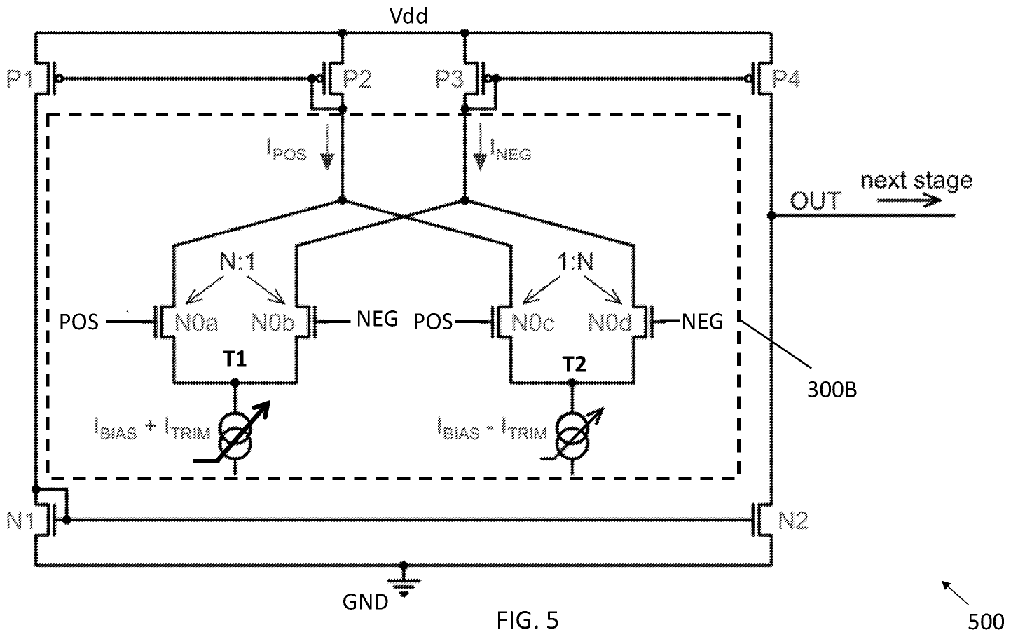

FIG. 5 is another diagram of an apparatus comprising a signal processing circuit 500 and an input stage 300B for a signal processing circuit 500, in accordance with a fifth embodiment of the present disclosure. The signal processing circuit 400 in this example embodiment is an OTA 500 which uses the example embodiment of the input stage 300B shown in FIG. 3B. The input stage 300B of FIG. 5 is taken to have the same functionality and meaning as the input stage 300B of FIG. 3B. This example embodiment of the input stage can also be used in other types of amplifier circuits as well as different types of comparator circuits. The OTA 500 shown here has the same structure as the one of the prior art in FIG. 1 except the input stage 110 has been replaced with an embodiment 300B of the present disclosure. The alternative embodiment of the input stage of the present disclosure shown in FIG. 3A can also be used in the OTA 500.

For all embodiments of the present disclosure, the value of I_{TRIM} and the skewing factor are related and are chosen depending on the purpose of the signal processing circuit that the input stage is to be used for or the size of the circuit. Smaller input stages will require a higher skewing factor, as smaller devices have a larger percentual error in, for example, size and doping. The range for the trimming current I_{TRIM} must be set accordingly. The skewing factor N and the range of I_{TRIM} must be large enough to compensate for the fabrication mismatch. If the skewing factor is large, the range of I_{TRIM} does not need to be so large. On the other hand, if the skewing factor is marginal then the I_{TRIM} range will be equal to I_{BIAS}.

The example embodiments of FIGS. 3A and 3B described in the present disclosure allow for the trimming of the voltages offset of an input stage comprising at least one differential pair for a signal processing circuit. This trimming occurs outside the signal path of the circuits and therefore does not slow down the signal processing circuit. There is the additional benefit that the embodiments of the present disclosure allow for fast, accurate and low power designs. The embodiments are beneficial for a wide range of designs which utilize differential pairs.

Various improvements and modifications may be made without departing from the scope of the disclosure.

A skilled person will therefore appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

1. An input stage for a signal processing circuit, the input stage comprising:
a first differential pair; and
a second differential pair;
wherein the first differential pair and the second differential pair have opposing skews which controls a voltage offset of the input stage.

2. The input stage of claim 1, wherein the signal processing circuit is one of an amplifier or a comparator.

3. The input stage of claim 2, wherein the amplifier is an operational transconductance amplifier.

4. The input stage of claim 1, wherein the first differential pair comprises a first transistor and a second transistor such that the first transistor and second transistor have a skew in a first direction.

5. The input stage of claim 4, wherein the second differential pair comprises a third transistor and a fourth transistor such that the third transistor and fourth transistor have a skew in a second direction, where the second direction is opposite to the first direction.

6. The input stage of claim 5, wherein the first transistor, second transistor, third transistor and fourth transistor are one of a metal oxide semiconductor or a bipolar transistor.

7. The input stage of claim 5, wherein the first transistor, second transistor, third transistor and fourth transistor each comprise an output terminal such that the output terminal of the first transistor and the third transistor are coupled together to form a positive node and the output terminal of the second and the fourth transistor are coupled together to form a negative node.

8. The input stage of claim 7, wherein the positive node is configured to carry a first current and the negative node is configured to carry a second current.

9. The input stage of claim 8, wherein the first transistor and the third transistor each comprise a control terminal, the control terminal being configured to receive a positive input, such that the positive inputs of the control terminals of the first transistor and third transistor are coupled together.

10. The input stage of claim 9, wherein the second transistor and the fourth transistor each comprise a control terminal, the control terminal being configured to receive a negative input, such that the negative inputs of the control terminals of the second transistor and fourth transistor are coupled together.

11. The input stage of claim 10, wherein the first transistor, second transistor, third transistor and fourth transistor each further comprise an input terminal such that the input terminals of the first transistor and the second transistor are together coupled to form a first tail node and the input terminal of the third transistor and the fourth transistor are coupled together to form a second tail node.

12. The input stage of claim 10, wherein the first tail node and the second tail node are configured to receive a bias current.

13. The input stage of claim 12, wherein the first current and the second bias currents are equal and the bias currents are not adjusted.

14. The input stage of claim 12, wherein the first current and the second current are not equal and either:
the bias current at the first tail node is adjusted; or
the bias current at the second tail node is adjusted; or
the bias current at the first tail node and the second tail node are adjusted.

15. The input stage of claim 14, wherein the first current and the second current are equal after the bias current is adjusted.

16. The input stage of claim 15, wherein the bias current is adjusted by a trimming current.

17. The input stage of claim 16, wherein:
when the bias current is adjusted by the trimming current, the voltage offset is controlled such that the voltage offset of the input stage is minimised.

18. The input stage of claim 16, wherein:
when the bias current is adjusted by the trimming current, the voltage offset is controlled such that the voltage offset of the input stage is set to a pre-determined value.

19. The input stage of claim 16, wherein either:
the trimming current is added to or taken away from the bias current at the first tail node; or
the trimming current is added to or taken away from the bias current at the second tail node; or
the trimming current is added to the bias current at the first tail node and the trimming current is taken away from the bias current at the second tail node; or
the trimming current is taken away from the bias current at the first tail node and the trimming current is added to the bias current at the second tail node.

20. The input stage of claim 19, wherein the trimming current has an absolute value dependent on the skew of the first differential pair, the skew of the second differential pair and the voltage offset of the input stage.

21. An apparatus comprising:
a signal processing circuit,
an input stage for the signal processing circuit, the input stage comprising a first differential pair and a second differential pair wherein the first differential pair and the second differential pair have opposing skews which controls a voltage offset of the input stage.

22. A method for controlling a voltage offset of an input stage for a signal processing circuit, the method comprising:
providing the input stage with a first differential pair and a second differential pair, wherein the first differential pair and the second differential pair have opposing skews.

23. The method of claim 22, wherein:
the first differential pair and the second differential pair are configured to receive a bias current; and
the bias current of either the first differential pair, or the second differential pair, or both the first and the second differential pair is adjusted by a trimming current such that the voltage offset of the input stage is controlled.
